(19) United States
(12) Patent Application Publication
(10) Pub. No.: US 2012/0138989 A1
(43) Pub. Date: Jun. 7, 2012

(54) LIGHT EMITTING DEVICE PACKAGE AND METHOD OF MANUFACTURING THE SAME

(76) Inventors: Cheol Jun YOO, Cheonan (KR); Young Hee Song, Seongnam (KR); Seong Deck Hwang, Seoul (KR); Sang Hyun Lee, Suwon (KR)

(21) Appl. No.: 13/309,139

(22) Filed: Dec. 1, 2011

(30) Foreign Application Priority Data
Dec. 6, 2010 (KR) 10-2010-0123508

(51) Int. Cl. H01L 33/52; H01L 33/58

(52) U.S. Cl. 257/98; 438/27; 257/E33.059; 257/E33.068

(57) ABSTRACT

A light emitting device package includes a plurality of lead frames separated from one another; at least one light emitting device provided with a wire bonding pad attached to a lower surface thereof opposite an upper light emission surface thereof, and mounted on the lead frames such that the wire bonding pad is positioned in a space between the lead frames; a bonding wire electrically connecting the wire bonding pad to the lead frame through the space between the lead frames; and a mold part encapsulating the lead frames, the light emitting device and the bonding wire, and having a reflection groove formed in an upper surface thereof to expose the light emission surface therethrough and a pad groove formed in a bottom surface thereof to expose a portion of the lead frame so as to form a solder pad thereon.

### CROSS-REFERENCE TO RELATED APPLICATIONS

This application claims the priority of Korean Patent Application No. 10-2010-0123508 filed on Dec. 6, 2010, in the Korean Intellectual Property Office, the disclosure of which is incorporated herein by reference.

### BACKGROUND OF THE INVENTION

1. Field of the Invention

The present invention relates to a light emitting device package and a method of manufacturing the same.

2. Description of the Related Art

In general, alight emitting device package containing a light emitting diode (LED) in which a light emission operation is performed in response to an electrical signal is widely used in various kinds of electronic products including a mobile communications terminal such as a personal mobile phone, a personal digital assistant (PDA), or the like.

A package structure, according to a related art, having an LED installed therein, generally has a cup-shaped cavity formed in a package body thereof formed of a high reflectivity material to reduce light loss in light emitted from a light emitting device and has the cavity filled with a silicon-based or epoxy-based gel-type polymer having relatively prominent light transmittance characteristics and heat resistance after installing the light emitting device in the cavity.

In this case, since a light emission surface and a bonding position of a wire exist on the same level, light may not be emitted from the light emission surface in sufficient quantities due to intervening elements such as the bonding pads or the like, bonded to the light emission surface, thus decreasing light extraction efficiency. In addition, since a separate heat sink should be provided on a lower part of the light emitting device, the manufacturing of a mold may be complicated and manufacturing costs may increase.

### SUMMARY OF INVENTION

An aspect of the present invention provides a light emitting device package and a method of manufacturing the same, which is capable of having significantly increased light extraction efficiency by changing a position in which a wire bonding pad is located so as to substantially enlarge a light emission surface.

Another aspect of the present invention provides a light emitting device package and a method of manufacturing the same, having a simplified overall manufacturing process due to a post-molding process, thereby improving productivity and product reliability.

According to an aspect of the present invention, there is provided a light emitting device package including: a plurality of lead frames disposed to be separated from one another; at least one light emitting device provided with a wire bonding pad attached to a lower surface thereof opposite to an upper light emission surface thereof, and mounted on the lead frames such that the wire bonding pad is positioned in a space between the lead frames; a bonding wire electrically connecting the wire bonding pad to the lead frame through the space between the lead frames; and a mold part encapsulating the lead frames, the light emitting device and the bonding wire, and having a reflection groove formed in an upper surface thereof to expose the light emission surface to the outside therethrough and a pad groove formed in a bottom surface thereof to expose a portion of the lead frame so as to form a solder pad thereon.

The light emitting device package may further include an envelope part formed within the reflection groove to cover the light emission surface.

The envelope part may contain any one of a fluorescent material, a diffusion material and a mixture thereof.

The light emitting device package may further include a lens part provided on the mold part.

The lead frame may include an open part formed to penetrate through a portion thereof corresponding to a position of the wire bonding pad, through which the wire bonding pad of the light emitting device is downwardly exposed.

The mold part may be formed such that a bottom surface of the reflection groove is on the same level as the light emission surface of the light emitting device.

The mold part may be formed such that the bottom surface of the reflection groove is on the same level as an upper surface of the lead frame on which the light emitting device is mounted.

The bottom surface of the reflection groove may be circular, quadratic or polygonal.

According to another aspect of the present invention, there is provided a method of manufacturing a light emitting device package, including: preparing a light emitting device provided with a wire bonding pad attached to a lower portion surface opposite to an upper light emission surface thereof; mounting at least one light emitting device on a plurality of lead frames disposed to be separated from one another allowing for the wire bonding pad to be positioned in a space between the lead frames; electrically connecting the light emitting device to the lead frame by bonding one end of the bonding wire to the wire bonding pad and bonding the other end thereof to the lead frame, the other end thereof extending toward a lower surface of the lead frame through the space between the lead frames; forming a mold part through a molding process to encapsulate the light emitting device mounted on the lead frames together with the bonding wires by applying a resin thereto, the mold part being provided with a reflection groove formed in an upper surface thereof to expose the light emitting device therethrough and provided with a pad groove formed in a bottom surface thereof to expose a portion of the lead frame therethrough so as to form a solder pad thereon; and forming an envelope part within the reflection groove to cover the light emitting device.

The preparing of the light emitting device may further include forming a fluorescent substance layer on the light emission surface.

The mounting of the light emitting device may include forming an open part to penetrate through the lead frame, and mounting the light emitting device on the lead frames such that the wire bonding pad of the light emitting device is exposed toward a lower surface of the lead frame through the open part.

The electrical connecting of the light emitting device and the lead frame may include bonding one end of the bonding wire to the wire bonding pad and bonding the other end thereof to the lead frame, the other end thereof extending toward a lower surface of the lead frame through the open part.

In addition, the forming of the mold part may include performing a molding process such that a light emitting device is disposed within the reflection groove or a plurality thereof are disposed therein.

The forming of the mold part may include performing the molding process such that the bottom surface of the reflection groove is equal to that of a height of the light emission surface of the light emitting device and thus the light emission surface is exposed through the reflection groove.

In addition, the forming of the mold part may include performing the molding process such that the bottom surface of the reflection groove is on the same level as an upper surface of the lead frame on which the light emitting device is mounted so as to expose the light emission surface, a side surface of the light emitting device and an upper portion of the lead frame through the reflection groove.

The method may further include adapting a lens part on the mold part.

The method may further include arranging a frame sheet on which the plurality of lead frames are formed before the mounting of the light emitting device is performed.

The method may further include forming a solder pad in the pad groove after the forming of the mold part is performed.

The method may further include dicing along a cutting line.

### BRIEF DESCRIPTION OF DRAWINGS

The above and other aspects, features and other advantages of the present invention will be more clearly understood from the following detailed description taken in conjunction with the accompanying drawings, in which:

FIG. 1 schematically shows a light emitting device package according to an embodiment of the present invention;

FIGS. 2A and 2B schematically show a further embodiments of the light emitting device package of FIG. 1;

FIGS. 3A and 3B schematically show a connection state of a light emitting device and lead frames, using a bonding wire, through a space between the lead frames referred to in FIG. 1;

FIGS. 4A and 4B schematically illustrate a connection state between a plurality of light emitting devices shown in FIG. 3;

FIGS. 5A, 5B and 5C schematically illustrate a mold part encapsulating the light emitting device and the lead frames shown in FIG. 3;

FIGS. 6A, 6B and 6C schematically illustrate a varied example of FIG. 5;

FIGS. 7A, 7B and 7C schematically illustrate another varied example of FIG. 5;

FIGS. 8A and 8B schematically show a mold part encapsulating the light emitting device and the lead frames shown in FIG. 4;

FIGS. 9A and 9B schematically show a pad groove of the mold part shown in FIG. 1;

FIGS. 10A and 10B schematically show a connection state between the light emitting device and the lead frames, using a bonding wire, through an open part of the lead frames shown in FIG. 3;

FIG. 11 schematically shows a frame sheet on which a plurality of lead frames are patterned according to an embodiment of the present invention;

FIG. 12 schematically shows the open part formed on the lead frame shown in FIG. 11;

FIGS. 13A and 13B schematically show the light emitting device mounted on the lead frames shown in FIG. 11;

FIGS. 14A and 14B schematically show a connection state of the light emitting device and the lead frames shown in FIG. 13 by using a bonding wire;

FIGS. 15A and 15B schematically show the mold part encapsulating the light emitting device and the lead frames shown in FIG. 14;

FIGS. 16A and 16B schematically show the envelope part formed in the mold part shown in FIG. 15;

FIGS. 17A and 17B schematically show a lens part adapted on the mold part shown in FIG. 16;

FIG. 18 schematically shows a solder pad formed in the mold part shown in FIG. 17; and

FIG. 19 schematically shows a process of dicing along a cutting line into separate light emitting device packages.

### DETAILED DESCRIPTION OF PREFERRED EMBODIMENT

Exemplary embodiments of the present invention will now be described in detail with reference to the accompanying drawings such that they could be easily practiced by those having skill in the art to which the present invention pertains. However, in describing the exemplary embodiments of the present invention, detailed descriptions of well-known functions or constructions will be omitted so as not to obscure the description of the present invention with unnecessary detail.

In addition, like reference numerals denote like elements throughout the drawings.

Unless explicitly described to the contrary, the word “comprise” and variations such as “comprises” or “comprising,” will be understood to imply the inclusion of stated elements but not the exclusion of any other elements.

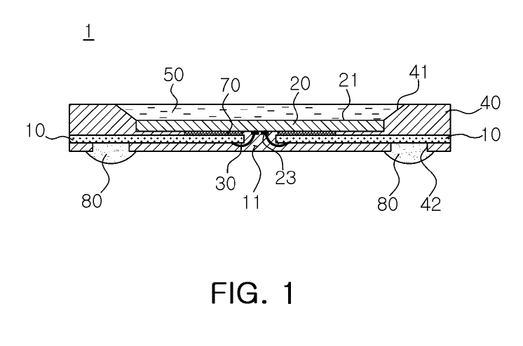

According to an embodiment of the present invention, a light emitting device package will be described with reference to FIGS. 1 to 9.

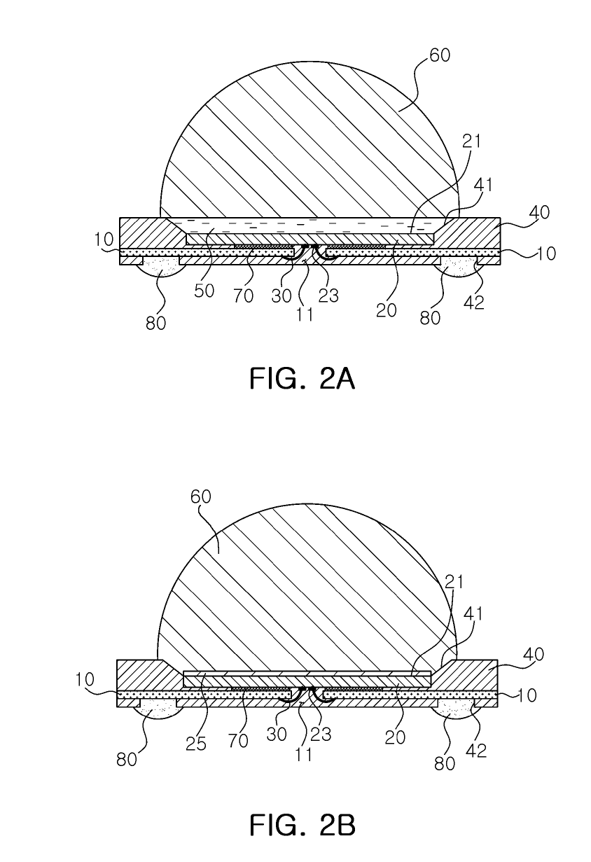

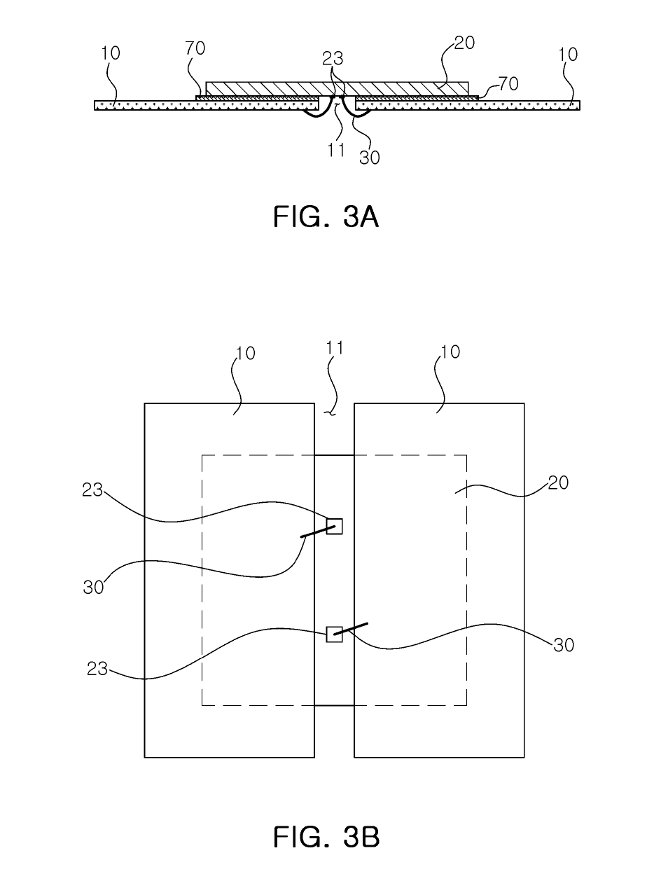

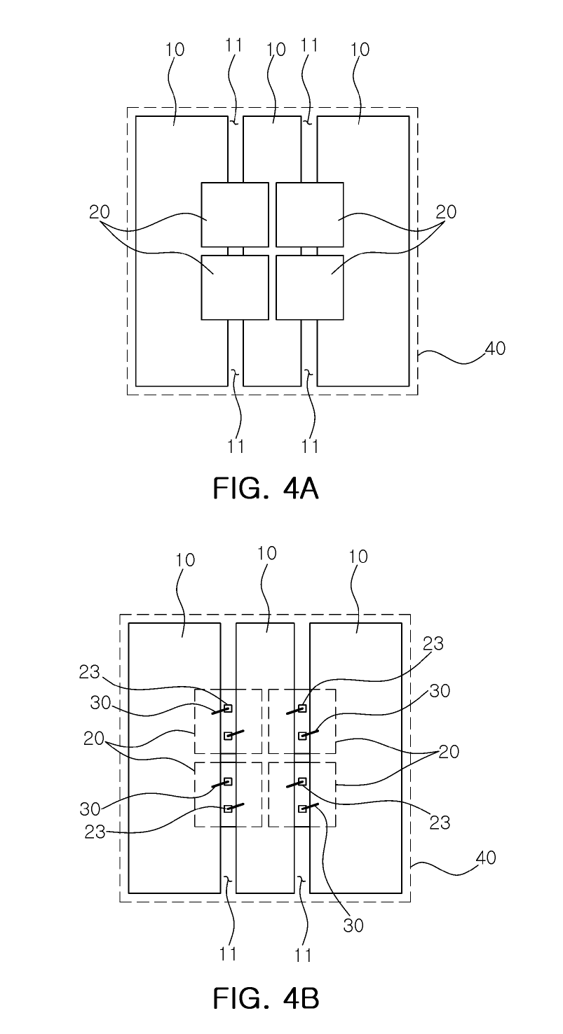

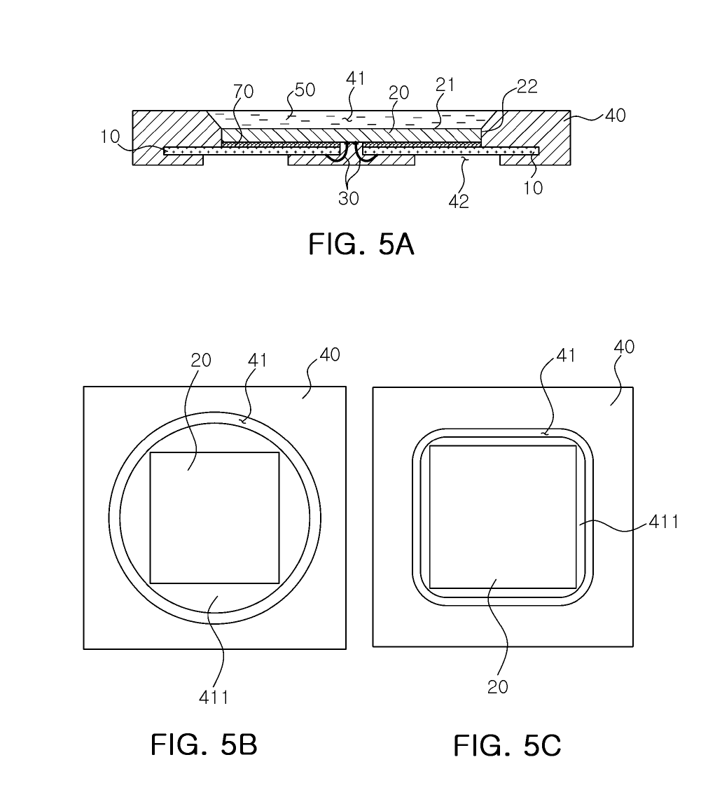

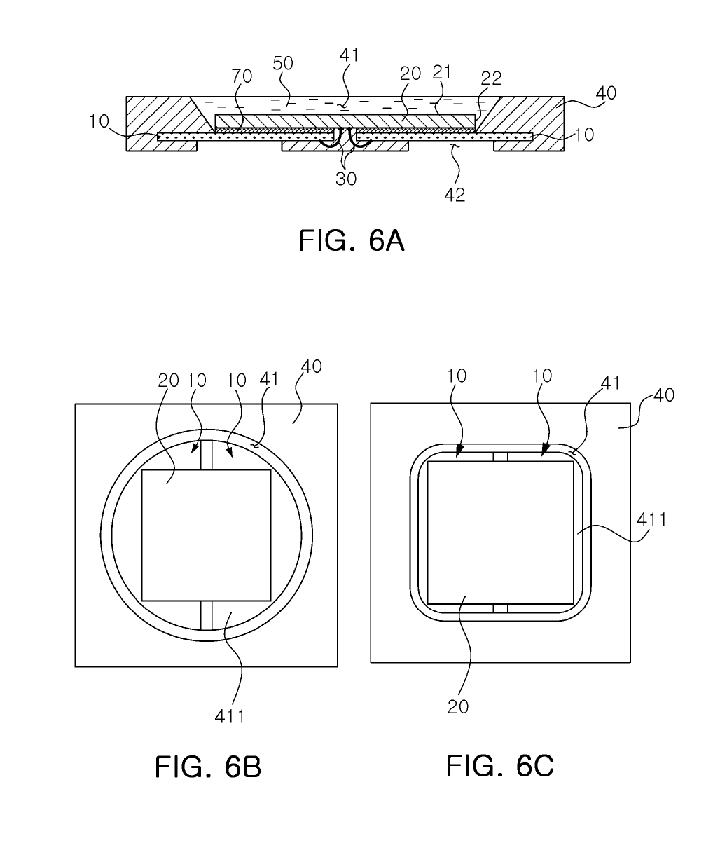

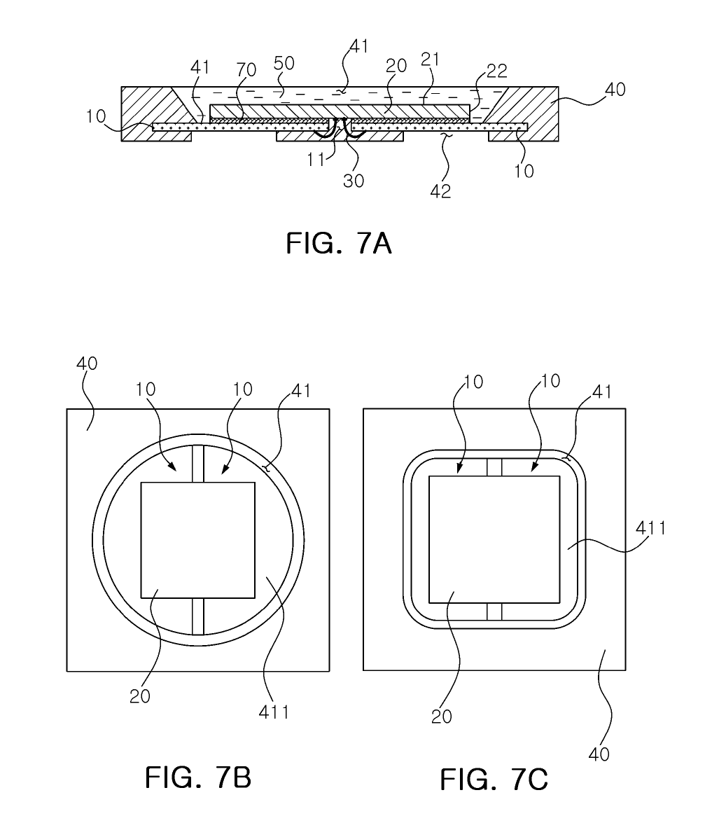

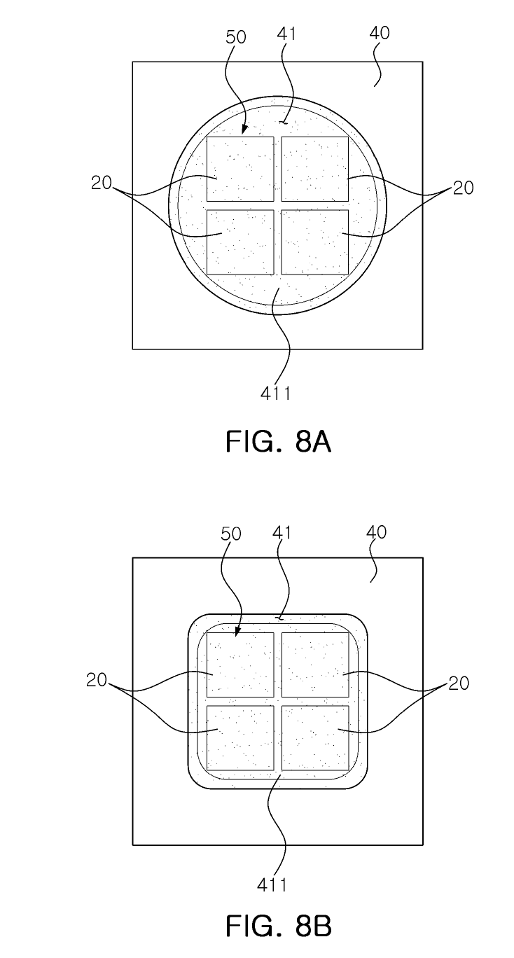

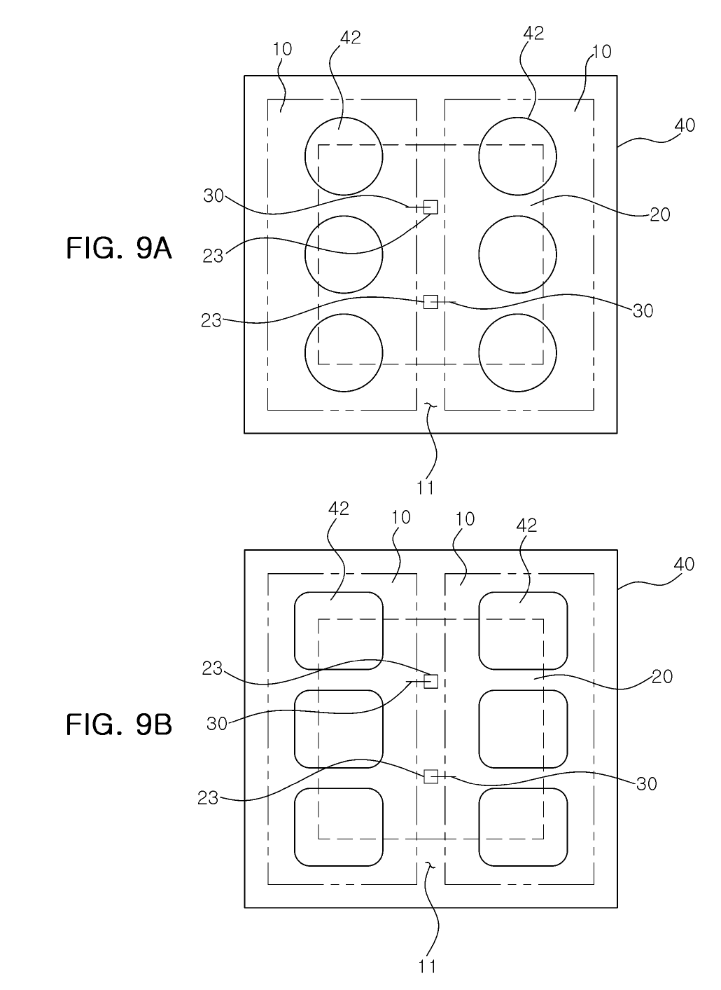

FIG. 1 schematically shows a light emitting device package according to an embodiment of the present invention, and FIGS. 2A and 2B schematically show embodiments of the light emitting device package of FIG. 1. FIGS. 3A and 3B schematically show a connection state of a light emitting device and lead frames, using a bonding wire, through a space between the lead frames referred to in FIG. 1. FIGS. 4A and 4B schematically illustrate a connection state between a plurality of light emitting devices shown in FIG. 3. FIGS. 5A, 5B and 5C schematically illustrate a mold part encapsulating the light emitting device and the lead frames shown in FIG. 3, FIGS. 6A, 6B and 6C schematically illustrate a varied example of FIG. 5, and FIGS. 7A, 7B and 7C schematically illustrate another varied example of FIG. 5. FIGS. 8A and 8B schematically show a mold part encapsulating the light emitting device and the lead frames shown in FIG. 4, and FIGS. 9A and 9B schematically show a pad groove of the mold part shown in FIG. 1.

Referring to FIGS. 1 and 2, according to an embodiment of the present invention, a light emitting device package 1 may include a plurality of lead frames 10, at least one light emitting device 20, a bonding wire 30 and a mold part 40, and may further include an envelope part 50 formed to cover the light emitting device and a lens part 60 disposed on the mold part.

The plurality of lead frames 10 are separated from one another by a predetermined interval so as not to be electrically connected to one another. FIG. 3 shows two lead frames 10 used in the light emitting device, and FIG. 4 shows three lead frames 10 which may be used therein, but which the light emitting device is not limited thereto. The lead frame 10 may transfer an electrical signal to the light emitting device 20 mounted thereon, and may made of metal such as Al, Cu, or the like, having effective heat conductivity so as to discharge heat generated from the light emitting device 20 to the outside. The lead frame 10 may have a plurality of through holes (not shown) penetrating therethrough. As such, the mold part 40, to be described below, is applied to upper and lower surfaces of the lead frame 10 and the through holes are simultaneously filled therewith, thereby allowing the lead frame 10 to become solidified while remaining fixed to the inside of the mold part 40.

The light emitting device 20 is a semiconductor device able to emit light having a given wavelength in response to an electrical signal applied from the outside, and may include light emitting chips or a light emitting device package having light emitting chips mounted therein. The light emitting device 20 may emit blue light, red light or green light according to the material contained therein, and may also emit white light.

The light emitting device 20 may emit light to the outside through a light emission surface 21 provided as an upper surface thereof, and a lower surface opposite to the upper surface may be provided with a wire bonding pad 23 receiving the electrical signal. The light emitting device 20 may be mounted on the lead frame 10 such that the wire bonding pad 23 is positioned in a space 11 between the lead frames 10. Therefore, when the light emitting device 20 is mounted on the lead frames 10, the wire bonding pad 23 provided with a lower surface of the light emitting device 20 is exposed toward the lower surface of the lead frame 10 through the space 11 between the lead frames.

The light emitting device 20 may be bondedly fixed to the lead frames 10 through a bonding member 70 provided between the lead frame and the light emitting device. The bonding member 70 may be formed as a tape type adhesion layer on the lead frame 10, or formed as a paste type layer thereon using a spraying method, a printing method, a dispensing method, or the like. In this case, the tape or paste may have a high density of high heat transfer filler. Further, the light emitting device 20 may be directly adhered to the lead frames 10 through metal bonding, and in this case, a heat transfer characteristic between the light emitting device 20 and the lead frames 10 may be relatively more effective. A single light emitting device 20 may be mounted on the lead frames 10 as shown in FIG. 3, or a plurality of light emitting devices 20 may be arranged in a matrix structure or in a line, or others having various structures, such as those shown in FIG. 4. The light emitting devices arrayed within a single package may be the same or different.

The bonding wire 30 may electrically connect the light emitting device 20 with the lead frames through the space as an interval between the lead frames. Described in detail, one end of the bonding wire 30 is bonded to the wire bonding pad 23 of the light emitting device 20, and the other end thereof is bonded to the lead frame 10 by being extending toward a lower surface of the lead frame 10.

The mold part 40 may encapsulate the light emitting device 20 mounted between the lead frame 10 and the lead frame 10, and the bonding wire 30 electrically connecting the lead frame 10 to the light emitting device 20, while supporting the light emitting device and the bonding wire therein. A reflection groove 41 may be formed on an upper surface of the mold part 40 to which the light emission surface 21 of the light emitting device 20 is exposed, and a pad groove 42 to which the lead frame 10 is partially exposed may be formed on a bottom surface of the mold part 40. In the pad groove 42, a solder pad 80 is formed to be electrically connected to a circuit wiring (not shown) of a substrate not shown in the drawings on which the light emitting device package 1 is mounted.

As shown in FIGS. 5A, 6A and 7A, the reflection groove 41 may have an inwardly tapered cup-like structure in which an inner surface of the reflection groove surrounding a side surface of the light emitting device 20 is downwardly inclined from a lower part thereof toward the light emitting device 20. The reflection groove 41 may be formed in such a manner that a distance of a depth thereof is greater than that of a height of the light emitting device 20 so that the light emitting device 20 is not protruded from an upper part of the mold part 40. The reflection groove 41 may be provided with a bottom surface 411 that is circular, as shown in FIGS. 5B, 6B and 7B, quadrangular, as shown in FIGS. 5C, 6C and 7C, or is pentagonal or hexagonal, or the like, in consideration of a light reflection characteristic.

As shown in FIG. 5A, in the mold part 40, the bottom surface 411 of the reflection groove 41 may be formed in such a manner that a bottom surface thereof is on the same level as the light emission surface 21. In this case, only the light emission surface 21 of the light emitting device 20 is exposed to the outside through the reflection groove 41, and a side surface 22 of the light emitting device 20 is molded within the mold part 40 so as not to be exposed thereto. Further, as shown in FIGS. 6A and 7A, the bottom surface 411 of the reflection groove 41 may be formed such that an uppermost height thereof is equal to that of an uppermost height of the lead frame 10 on which the light emitting device 20 is mounted. In this case, the light emission surface 21 as an upper surface of the light emitting device 20, and the side surface 22 thereof are exposed to the outside through the reflection groove 41, and a portion of the lead frame 10 on which the light emitting device 20 is mounted is also exposed to the outside through the reflection groove 41.

The pad groove 42, formed in a lower surface of the mold part 40 may be circular or quadrangular, as shown in FIGS. 9A and 9B, or variously shaped or the like, and a plurality of pad grooves 42 may be formed in a length direction of the respective frames 10 in order for effective heat discharge and a stable mounting.

An envelope part 50 may be formed within the reflection groove 41 to cover and protect the light emission surface 21. The envelope part 50 may be formed of a transparent resin such that light emitted from the light emitting device 20 can be efficiently discharged to the outside. The envelope part 50 may contain fluorescent material, by which a wavelength of light generated from the light emitting device 20 may be converted into a required wavelength. For example, blue light may be converted in white light. The envelope part 50 may contain a diffusion material to diffuse light, in addition to the fluorescent material, or contain a mixture thereof.

As shown in FIG. 5A, when the bottom surface 411 of the reflection groove 41 is formed to be equal to a distance between the height thereof and the height of the light emission surface 21 of the light emitting device 20 such that only the light emission surface 21 is exposed to the outside through the reflection groove 41, the envelope part 50 containing the fluorescent material may distribute the fluorescent material onto the light emission surface 21 so as to reduce the required amount of high-priced fluorescent material. As shown in FIGS. 6A and 7A, when the bottom surface 411 of the reflection groove 41 is formed to be on the same level as the upper surface of the lead frame 10 on which the light emitting device 20 is mounted to expose the light emission surface 21 and the side surface 22 to the outside through the reflection groove 41, the envelope part 50 may distribute fluorescent material on the light emission surface 21 and the side surface 22, thereby improving dark areas between the light emitting devices 20 particularly in a structure in which the plurality of light emitting devices 20 are arranged in a matrix type as shown in FIGS. 8A and 8B.

The lens part 60 may be formed on the mold part 40 as shown in FIG. 2A to cover the envelope part 50. The lens part 60 may be formed to have an upwardly convex dorm shape to improve an orientation angle of emitted light, but is not limited thereto. The lens part 60 may be formed directly on the mold part 40 using a molding method such as compression molding or transfer molding or the like, or a porting method using a dispenser, or may be manufactured through a separate process and bonded to the mold part 40 using an adhesive. Further, as shown in FIG. 2B, the lens part 60 may be formed within the reflection groove 41 of the mold part 40 to directly cover the light emitting device 20. In this case, the envelope part 50 may not be employed, and a fluorescent substance layer 25 may be formed as a thin type on the light emission surface 21 of the light emitting device 20.

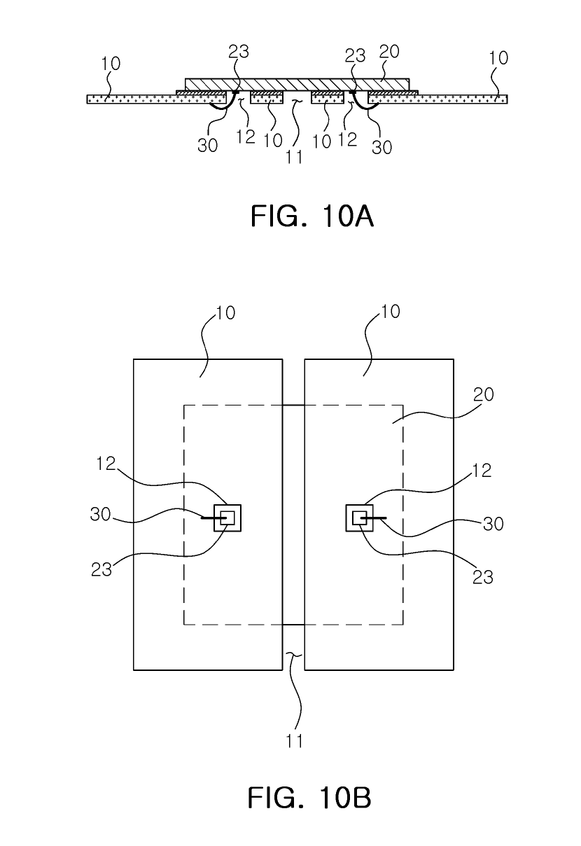

A light emitting device package according to another embodiment of the present invention will be described with reference to FIGS. 10A and 10B.

FIGS. 10A and 10B schematically show a connection state between a light emitting device and lead frames through open parts of the lead frames shown in FIG. 3, using a bonding wire.

The light emitting device package according to the embodiment of the present invention with reference to FIGS. 10A and 10B has a basic structure substantially equivalent to that of the embodiment referring to FIGS. 1 to 9. Meanwhile, since the embodiment with reference to FIGS. 10A and 10B has a difference from that of FIGS. 1 to 9 in view of the open part through which the wire bonding pad is exposed in connection with the lead frame, the repeated description with the above description will be omitted and the present embodiment will principally be described below in connection with the constitution of the lead frame 10.

As shown in FIG. 10A, the lead frame 10 may be provided with open parts 12 penetratingly formed in positions corresponding to the wire bonding pads 23, such that the wire bonding pads 23 of the light emitting device 20 may be downwardly exposed. Therefore, even when the wire bonding pad 23 is not positioned in the space 11 between the lead frames 10, the light emitting device 20 may be mounted in such a manner that the wire bonding pad 23 is downwardly exposed regardless of the position in which the wire bonding pad 23 is disposed.

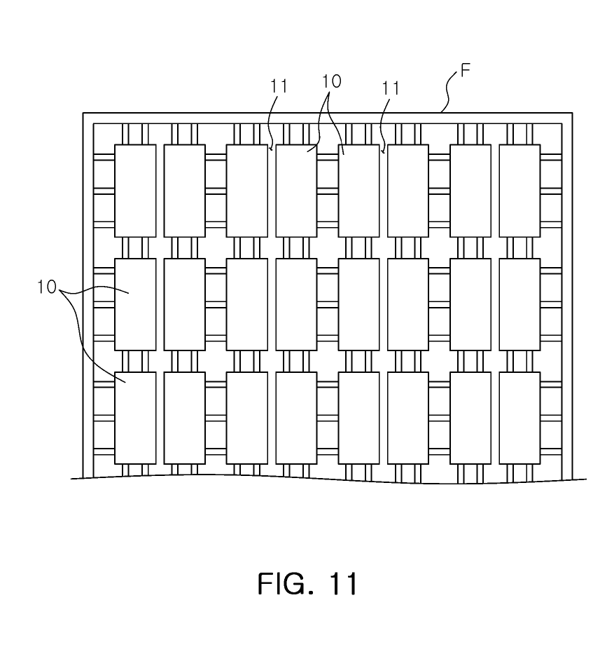

A method of manufacturing a light emitting device package will now be described according to an embodiment of the present invention with reference to FIGS. 11 to 19.

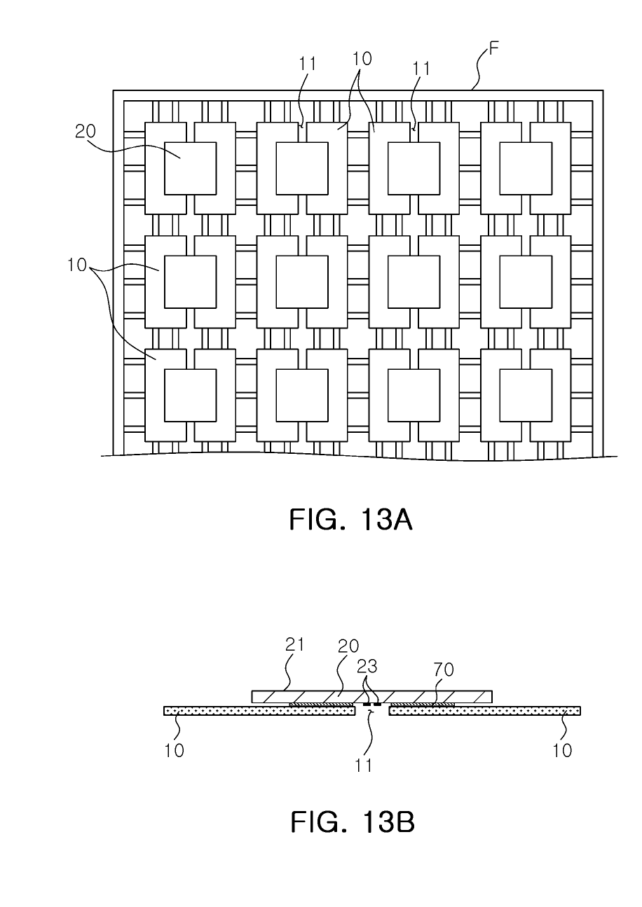

First, the light emitting device 20, which is provided with the bonding pads 23 that are positioned on a lower surface thereof opposite to the light emitting surface 21 as the upper surface of the light emitting device 20, may be prepared as shown in FIGS. 13A and 13B. Then, at least one light emitting device 20 may be mounted on the plurality of lead frames 10 disposed to be separated from each other, such that the wire bonding pads 23 are positioned in the space 11 between the lead frames 10.

The light emitting device 20 may be prepared by singulating a light emitting laminate of an n-type semiconductor layer, an active layer and a p-type semiconductor layer grown sequentially through a chemical vapor deposition apparatus (not shown) by separate dies on a wafer level. In this case, the fluorescent substance layer 25 may be further formed on the light emission surface 21 of the light emitting device 20. The fluorescent substance layer 25 may be formed to be entirely covered on the light emitting laminate or adhere thereto on the wafer level before being singulated into the separate dies.

Meanwhile, the method may further include arranging a frame sheet F on which the plurality of lead frames 10 are formed before mounting the light emitting devices 20. Described in more in detail, the plurality of lead frames 10 may be formed to be separated from one another by a predetermined interval by performing repeated patterning on a metal plate formed of material having a relatively large electrical conductivity and heat conductivity properties as shown in FIG. 11. The light emitting devices 20 may be arrayed corresponding to the patterned lead frames 10, in series or in a unit of groups in which the plurality of light emitting devices in a matrix type form a group. By this array structure the light emitting devices may be manufactured in a mass production.

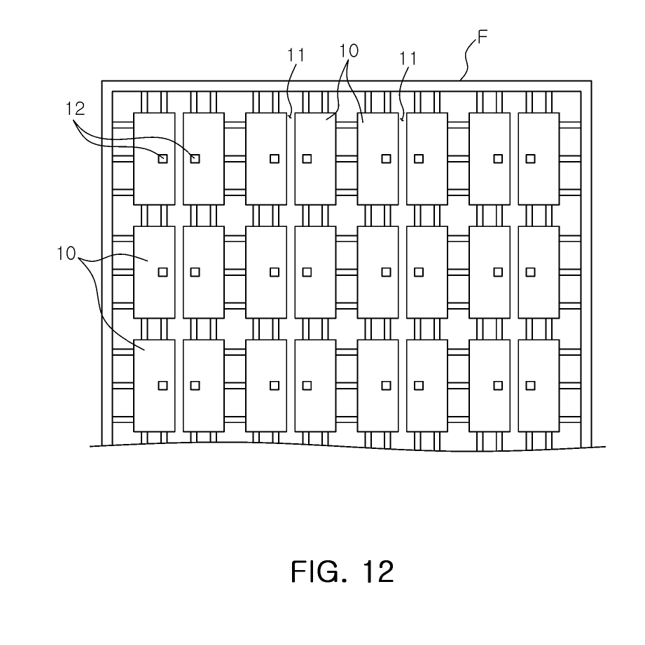

Meanwhile, the mounting of the light emitting device 20 may include forming the open part 12 penetrating through the lead frame 10, and mounting the light emitting device 20 on the lead frames 10 such that the wire bonding pads 22 of the light emitting device 20 are exposed toward lower surfaces of the lead frames 10 through the open parts 12. Described in detail, as shown in FIG. 12, the plurality of lead frames 10 may undertake a repeated patterning operation on the frame sheet F, and then the open parts 12 may be formed to penetrate through the lead frames 10 through a punching process or the like. The open parts 12 may be formed on positions corresponding to positions of the bonding pads 23 of the light emitting device 20, therefore the light emitting device 20 may be mounted on the lead frames such that the wire bonding pads 23 are positioned not only in the space 11 between the lead frames 10 but in the open parts 12. That is, light emitting devices 20 having various kinds of structures may be used according to embodiments of the present invention regardless of a position of the wire bonding pad 23. In the lead frame 10, a through hole (not shown) may be additionally formed for a solid combination with the mold part 40, including the formation of the open part 12. The light emitting device 20 may adhere to the lead frames 10 using the bonding members 70 that are applied between the light emitting device and the lead frames 10.

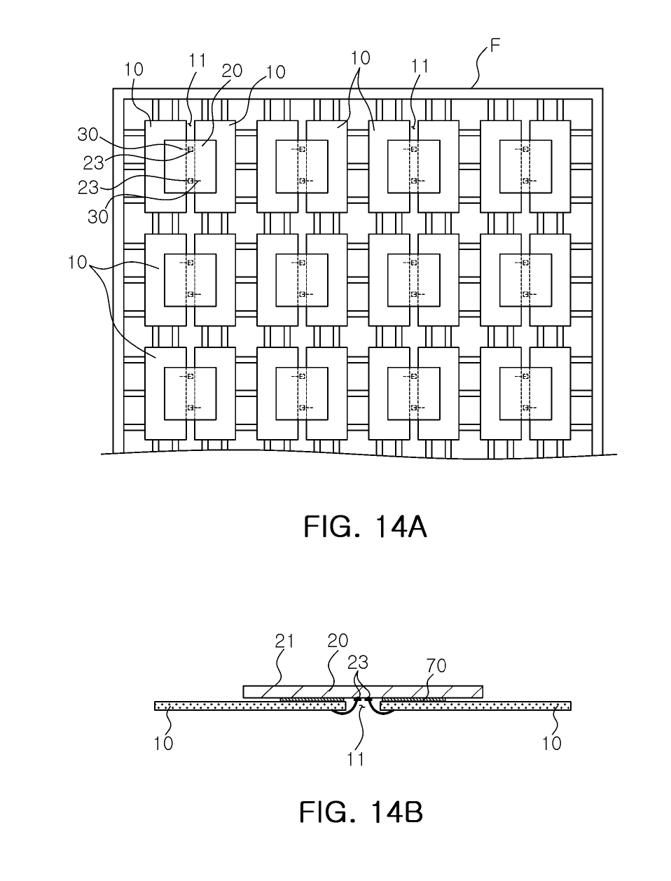

Subsequently, as shown in FIGS. 14A and 14B, one end of the bonding wire 30 may be bonded to the wire bonding pad 23, and another end thereof may extend toward a lower surface of the lead frame 10 through the space between the lead frames 10 so as to be bonded to the lead frame 10, thereby electrically connecting the light emitting device 20 to the lead frame 10. Further, when the wire bonding pad 23 is exposed to the outside through the open part 12, one end of the bonding wire 30 may bond to the wire bonding pad 23, and the other end thereof may extend toward the lower surface of the lead frame 10 through the open part 12 so as to be bonded to the lead frame 10 as shown in FIG. 10. As described above, the light emission surface 21 may not be interfered with by the bonding pad 23 or the bonding wire 30 by using the structure in which the wire bonding pads 23 and the bonding wires 30 are connected to the light emitting device 20 and the lower parts of the lead frames 10, thereby significantly increasing a light extraction efficiency.

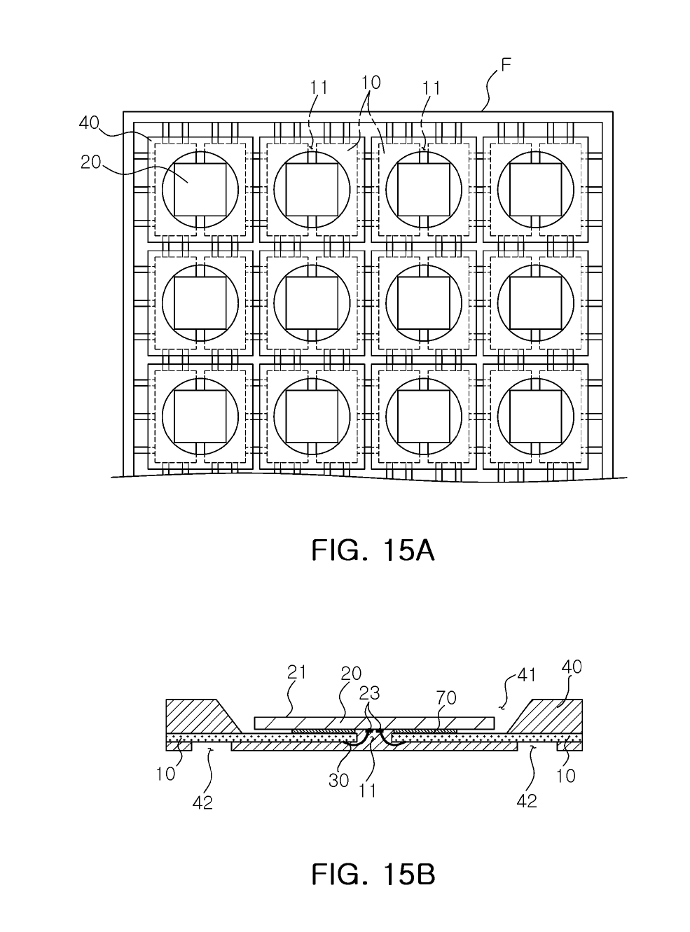

Then, the mold part 40 may be formed by applying resin thereto to encapsulate the light emitting device 20 mounted on the lead frames 10 together with the bonding wires 30 as shown in FIGS. 15A and 15B. At this time, the reflection groove 41 to which the light emitting device 20 is exposed may be formed in an upper surface of the mold part 40, and the pad groove 42 through which the lead frame 10 is partially exposed and in which the solder pad 80 will be formed, may be formed in a lower surface of the mold part 40, using a molding process. A light emitting device 20 may be disposed in the reflection groove 41 and molded to provide a single chip package structure, or a plurality of light emitting devices 20 may be disposed therein and molded to provide a multichip package structure.

In the mold part 40, the molding process may be performed such that the bottom surface of the bottom part 411 of the reflection groove 41 is on the same level as the light emission surface 21 of the light emitting device 20 and thus, only the light emission surface 21 may be exposed through the reflection groove 41 as shown in FIG. 5. Further, as shown in FIGS. 6 and 7, the mold part 40 may be adapted such that the bottom surface of the bottom part 411 of the reflection groove 41 is on the same level as the upper surface of the lead frame 10 on which the light emitting device 20 is mounted, and thus the light emission surface 21 of the light emitting device 20, the side surface 22 thereof and a portion of an upper surface of the lead frame 10 are exposed through the reflection groove 41. In this case, the exposed upper surface of the lead frame 10 may be plated with a plating layer (not shown) having a relatively high reflexibility, such as an Ag plating layer.

As described above, in a post molding method of forming the mold part 40 after the light emitting device 20 is mounted on the lead frames 10 and the wire bonding process is completed, an overall process may be simplified since a non-value added process such as a bake and the like before introducing resin material is omitted, unlike a pre-molding method of mounting a light emitting device in a state in which the existing mold part has been formed and of performing a wire bonding process. In addition, the molding process may be performed by controlling the structure of the reflection groove 41 to control a degree of exposure of the light emitting device 20, that is, only an upper surface thereof or the upper surface and the side surface thereof may be exposed, thereby preventing an unnecessary waste of space and significantly facilitating miniaturization and light collection efficiency.

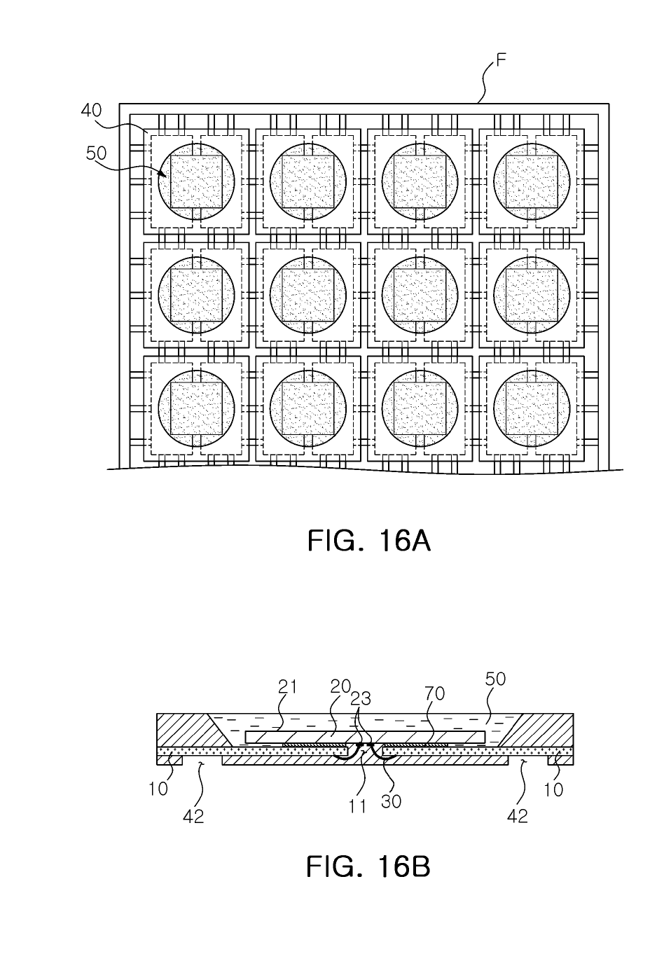

Then, as shown in FIGS. 16A and 16B, the envelope part 50 may be formed within the reflection groove 41 to cover the light emitting device 20. The envelope part 50 may be formed of a transparent resin so as to effectively discharge light irradiated from the light emitting device 20 to the outside, and may additionally contain a fluorescent material to convert a wavelength of light generated from the light emitting device 20 into a required wavelength or a diffusion material for a diffusion of light, and may be a mixture thereof. Meanwhile, when the fluorescent substance layer 25 is already formed on the light emitting device 20, the envelope part 50 may be empty or may contain diffusion material only.

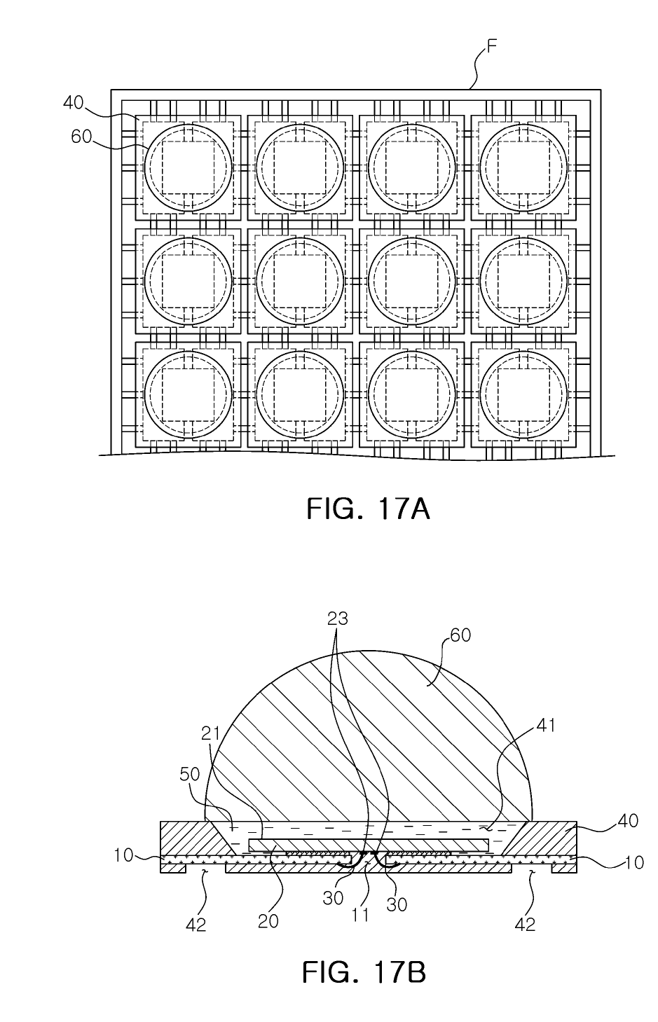

Subsequently, as shown in FIGS. 17A and 17B, the lens part 60 may be further provided to be attached to the mold part 40. The lens part 60 may be formed to have an upwardly convex dorm shape to improve an orientation angle of emitted light, but is not limited thereto. The lens part 60 may be formed directly on the mold part 40 by using a molding method such as a compression molding, transfer molding, or the like, or by using a porting method using a dispenser, or may be manufactured through a separate process to be adhered to the mold part 40 using an adhesive agent.

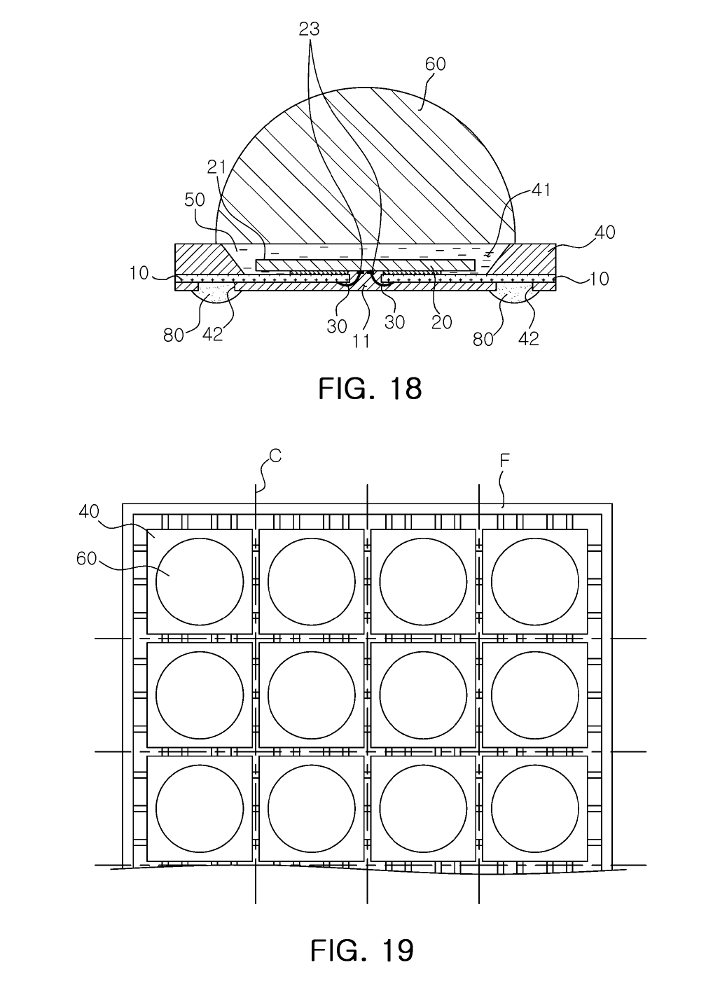

The solder pad 80 may be formed in the pad groove 42 that is provided in a lower surface of the mold part 40. The solder pad 80 may be formed after forming the mold part 40, or forming the envelope part 50 or forming the lens part 60 as shown in FIG. 18.

Then, a plurality of light emitting device packages may be manufactured by dicing along a cutting line C shown in FIG. 19.

As set forth above, according to an embodiment of the present invention, emitted light is not interfered with by a wire bonding pad or a bonding wire, thereby significantly increasing light extraction efficiency.

In addition, according to an embodiment of the present invention, a degree of freedom enjoyed in the design and number of wire bonding pads is improved, thereby improving electrical characteristics.

Further, according to an embodiment of the present invention, since the molding process is performed after chip bonding and wire bonding processes, a non-value added process such as bake processing and the like before introducing molding material may be omitted, thereby simplifying an overall process.

In addition, according to an embodiment of the present invention, wire bonding is performed within a chip area so as to reduce the overall size of a package.

Furthermore, since in a general epi-up (eg, p-side up) chip, light is also emitted from a side surface of a growth substrate, a fluorescent layer should be applied to cover not only an upper part of chip but a side surface thereof; however, according to an embodiment of the present invention, a fluorescent layer may be formed only on an upper part of chip by using a light reflection mold material encapsulating the periphery of the chip, thereby relatively easily forming a fluorescent layer and reducing a distribution of light quality.

In addition, according to an embodiment of the present invention, a wire is encapsulated using a molding material prominent in a mechanical physical characteristic, thereby enhancing reliability in a wire junction.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting device package comprising:
a plurality of lead frames disposed to be separated from one another;
at least one light emitting device provided with a wire bonding pad attached to a lower surface thereof opposite to an upper light emission surface thereof, and mounted on the lead frames such that the wire bonding pad is positioned in a space between the lead frames;
a bonding wire electrically connecting the wire bonding pad to the lead frame through the space between the lead frames; and
a mold part encapsulating the lead frames, the light emitting device and the bonding wire, and having a reflection groove formed in an upper surface thereof to expose the light emission surface to the outside therethrough and a pad groove formed in a bottom surface thereof to expose a portion of the lead frame so as to form a solder pad thereon.

2. The package of claim 1, further comprising an envelope part formed within the reflection groove to cover the light emission surface.

3. The package of claim 2, wherein the envelope part contains any one of a fluorescent material, a diffusion material and a mixture thereof.

4. The package of claim 1, further comprising a lens part provided on the mold part.

5. The package of claim 1, wherein the lead frame includes an open part formed to penetrate through a portion thereof corresponding to a position of the wire bonding pad, through which the wire bonding pad of the light emitting device is downwardly exposed.

6. The package of claim 1, wherein the mold part is formed such that a bottom surface of the reflection groove is on the same level as the light emission surface of the light emitting device.

7. The package of claim 1, wherein the mold part is formed such that the bottom surface of the reflection groove is on the same level as an upper surface of the lead frame on which the light emitting device is mounted.

8. The package of claim 6, wherein the bottom surface of the reflection groove is circular, quadratic or polygonal.

9. The package of claim 7, wherein the bottom surface of the reflection groove is circular, quadratic or polygonal.

10. A method of manufacturing a light emitting device package, comprising:
preparing a light emitting device provided with a wire bonding pad attached to a lower surface thereof opposite to an upper light emission surface thereof;
mounting at least one light emitting device on a plurality of lead frames disposed to be separated from one another allowing for the wire bonding pad to be positioned in a space between the lead frames;
electrically connecting the light emitting device to the lead frame by bonding one end of the bonding wire to the wire bonding pad and bonding the other end thereof to the lead frame, the other end thereof extending toward a lower surface of the lead frame through the space between the lead frames;
forming a mold part through a molding process to encapsulate the light emitting device mounted on the lead frames together with the bonding wires by applying a resin thereto, the mold part being provided with a reflection groove formed in an upper surface thereof to expose the light emitting device therethrough and provided with a pad groove formed in a bottom surface thereof to expose a portion of the lead frame therethrough so as to form a solder pad thereon; and
forming an envelope part within the reflection groove to cover the light emitting device.

11. The method of claim 10, wherein the preparing of the light emitting device further includes forming a fluorescent substance layer on the light emission surface.

12. The method of claim 10, wherein the mounting of the light emitting device includes forming an open part to penetrate through the lead frame, and mounting the light emitting device on the lead frames such that the wire bonding pad of the light emitting device is exposed toward a lower surface of the lead frame through the open part.

13. The method of claim 12, wherein the electrical connecting of the light emitting device and the lead frame includes bonding one end of the bonding wire to the wire bonding pad and bonding the other end thereof to the lead frame, the other end thereof extending toward a lower surface of the lead frame through the open part.

14. The method of claim 10, wherein the forming of the mold part includes performing a molding process such that respective one of the light emitting devices is disposed within the reflection groove or a plurality of the light emitting devices are disposed therein.

15. The method of claim 10, wherein the forming of the mold part includes performing the molding process such that the bottom surface of the reflection groove is on the same level as the light emission surface of the light emitting device and thus the light emission surface is exposed through the reflection groove.

16. The method of claim 10, wherein the forming of the mold part includes performing the molding process such that the bottom surface of the reflection groove is on the same level as an upper surface of the lead frame on which the light emitting device is mounted so as to expose the light emission surface, a side surface of the light emitting device and an upper portion of the lead frame through the reflection groove.

17. The method of claim 10, further comprising adapting a lens part on the mold part.

18. The method of claim 10, further comprising arranging a frame sheet on which the plurality of lead frames are formed before the mounting of the light emitting device is performed.

19. The method of claim 10, further comprising forming a solder pad in the pad groove after the forming of the mold part is performed.

20. The method of claim 10, further comprising dicing along a cutting line.
